(19) United States
(12) Patent Application Publication
(10) Pub. No.: US 2017/0158926 A1
(43) Pub. Date: Jun. 8, 2017

(54) LIQUID RESIN COMPOSITION, DIE ATTACHING METHOD USING SAME AND SEMICONDUCTOR DEVICE HAVING CURED PRODUCT OF SAME

(71) Applicant: Shin-Etsu Chemical Co., Ltd., Tokyo (JP)

(72) Inventors: Koichi TSUDA, Annaka-shi (JP); Tatsuya KANAMARU, Tokyo (JP)

(73) Assignee: Shin-Etsu Chemical Co., Ltd., Tokyo (JP)

(21) Appl. No.: 15/362,245

(22) Filed: Nov. 28, 2016

(30) Foreign Application Priority Data
Dec. 7, 2015 (JP) 2015-238685

(51) Int. Cl. C09J 163/00; C08L 63/00; H01L 23/00; H01L 21/78; H01L 23/495; C08G 59/14; H01L 21/683

(52) U.S. Cl. CPC C09J 163/00; C08G 59/1433; C08L 63/00; H01L 21/6836; H01L 21/78; H01L 23/49586; H01L 24/27; H01L 24/32; H01L 2221/68327; H01L 2221/68386; H01L 2224/27002; H01L 2224/2732; H01L 2224/29691; H01L 2924/0715

(57) ABSTRACT

Provided is a liquid resin composition superior in flatness after screen printing, stability in B stage, adhesiveness to a dicing tape, dicing property and adhesion to a lead frame. The liquid resin composition comprises given amounts of
(A) an epoxy resin having not less than two epoxy groups in one molecule;
(B) a curing agent having not less than two groups in one molecule that are reactive with epoxy groups;
(C) an acrylic resin;
(D) a curing agent;
(E) an inorganic filler;
(F) a diluent; and
(G) a dimethyl silicone.

### BACKGROUND OF THE INVENTION

Field of the Invention

The present invention relates to a liquid resin composition as an adhesive suitable for bonding a semiconductor element to a lead frame. Particularly, the invention relates to a liquid resin composition superior in thin film printability, stability in B stage, and adhesion to a lead frame; and a semiconductor device using a cured product of such composition.

Background Art

Epoxy resins have been used for various purposes, because they are superior in properties such as adhesion and heat resistance. Especially, liquid epoxy resins are widely used to produce electric and electronic parts. As a method for applying to a part a liquid epoxy resin or a composition mainly composed of such liquid epoxy resin, there have been known, for example, a spin coating method, a screen printing method and a dipping method. Among these methods, the spin coating method is widely used, because it allows coating layers of various shapes to be formed in an easy and productive manner.

As an epoxy resin-containing composition for screen printing, there has been known, for example, an adhesive varnish (JP-A-2005-60417) comprising (A) a polyimide silicone resin; (B) an epoxy resin; (C) an epoxy resin curing agent; (D) an inorganic filler; and (E) an organic solvent. Further, there has also been known a composition for lead frame fixation (JP-A-Hei-5-226571) that comprises an epoxy resin; a photopolymerization initiator; a thermoplastic elastomer prepolymer for imparting a toughness in B stage and after curing; a filler for improving a thixotropic property; and a solvent. The inventors of the present invention have previously provided a resin composition (Japanese Patent No. 5,278,457) that is superior in screen printability, can be applied in a way such that surface irregularities are controlled to a low level, is capable of easily reaching B stage when heated, has an excellent adhesiveness to a dicing tape in B stage, and has excellent dicing properties when dividing a silicon wafer.

However, as semiconductor packages have been progressively downsized, a chip, in most cases, is now bonded to a part of an inner lead with a die pad portion being omitted, in the case of a type of package where a chip is to be mounted on a lead frame. When bonding an inner lead and a chip to each other, an area on the lead to which the chip will adhere is smaller than an area of the top or rear surface of the chip. Thus, it is required in such case that an adhesive be able to maintain the adhesion between the inner lead and chip through a minute area. However, with regard to the conventional screen printing method employing a resin composition capable of reaching B stage, an adhesion force between a lead frame and a chip has been insufficient in a way such that there has been a problem that peelings or the like will occur at the time of performing molding and while a semiconductor element(s) are being used.

Further, it is important that the thickness of an adhesive layer exhibit a small variation for the purpose of stabilizing the reliability of a package. In order for this to happen, it is required that there be formed an adhesive layer having a uniform thickness and exhibiting a low level of surface irregularities, when a resin composition as an adhesive reaches B stage after screen printing.

Moreover, the semiconductor industry has seen a progress in division of labor and specialization where after printing an adhesive composition on a silicon wafer on which a circuit pattern has been formed and then allowing the composition to reach B stage, other companies may then, for example, take on dicing and an assembly step such as mounting semiconductor chips to lead frames. In such case, it is required that the B-staged adhesive composition be stable as a B-staged product, because the composition will be exposed to room temperature for a long period of time as it will be, for example, shipped and stored before the next step(s).

### SUMMARY OF THE INVENTION

Therefore, it is an object of the present invention to provide a liquid resin composition superior in thin film printability on a large area, capable of forming a stable B stage condition and thus exhibiting a favorable adhesion to a lead frame; a die attaching method using such composition; and a semiconductor device having a cured product of such composition.

The inventors of the present invention diligently conducted studies in view of the above concerns, and made the invention as follows. That is, the inventors found that a liquid resin composition containing, at given ratios, a spherical or pseudospherical inorganic filler with an average particle diameter of 0.05 to 5 μm and a scale-shaped inorganic filler with an aspect ratio (average particle diameter a/average thickness t) of 2 to 100 was superior in flatness after screen printing, stability in B stage, adhesiveness to a dicing tape, dicing property at the time of performing dicing, and adhesion to a lead frame. Here, in this specification, “B stage condition” refers to a state where the liquid resin composition has been primarily cured, semi-cured or temporarily cured; and “C stage condition” refers to a state where the curing reaction has completely ended.

That is, the present invention is

[1]

A liquid resin composition comprising:

(A) an epoxy resin having not less than two epoxy groups in one molecule;

(B) a curing agent having not less than two groups in one molecule that are reactive with epoxy groups, said curing agent being in an amount at which the groups in the component (B) that are reactive with epoxy groups are in an amount of 0.8 to 1.25 equivalents with respect to 1 equivalent of epoxy groups in the component (A);

(C) an acrylic resin having a molecular weight of not lower than 100,000, but lower than 1,000,000, said acrylic resin being in an amount of 5 to 900 parts by mass with respect to a total of 100 parts by mass of the components (A) and (B);

(D) a curing agent in an amount of 0.05 to 10 parts by mass with respect to the total of 100 parts by mass of the components (A) and (B);

(E) an inorganic filler in an amount of 50 to 600 parts by mass with respect to the total of 100 parts by mass of the components (A) and (B);

(F) a diluent in an amount of 10 to 900 parts by mass with respect to a total of 100 parts by mass of the components (A) to (D); and

(G) a dimethyl silicone that is in an amount of 0.01 to 2 parts by mass with respect to the total of 100 parts by mass of the components (A) and (B), and is represented by the following general formula (1) wherein n represents an integer of 0 to 2,000

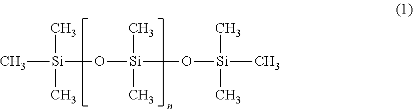

wherein 10 to 90% by mass of said inorganic filler (E) is a spherical or pseudospherical inorganic filler having an average particle diameter of 0.05 to 5 μm, and 90 to 10% by mass of said inorganic filler (E) is a scale-shaped inorganic filler having an average thickness t of 0.005 to 5 μm, an average particle diameter a of 0.05 to 15 μm and an aspect ratio (average particle diameter a/average thickness t) of 2 to 100.

[2]

The liquid resin composition according to [1], wherein a part of the component (A) is a silicone-modified epoxy resin, and/or a part of the component (B) is a silicone-modified curing agent, said silicone-modified components being in an amount of 0.1 to 5 parts by mass with respect to the total of 100 parts by mass of the components (A) and (B).

[3]

The liquid resin composition according to [1] or [2], wherein said spherical or pseudospherical inorganic filler is silica, alumina or a combination thereof.

[4]

The liquid resin composition according to [1] or [2], wherein said scale-shaped inorganic filler is mica, talc or a combination thereof.

[5]

The liquid resin composition according to any one of [1] to [4], wherein said diluent (F) is a solvent having a boiling point of 150 to 300° C.

[6]

The liquid resin composition according to any one of [1] to [5], wherein said liquid resin composition exhibits a thixotropic index of 0.8 to 1.5.

[7]

The liquid resin composition according to any one of [1] to [6], wherein said liquid resin composition in B stage exhibits a lowest melt viscosity of 200 to 100,000 Pa·s at 50 to 200° C.

[8]

A silicon chip die attaching method comprising:

(1) a liquid resin composition coating step of applying the liquid resin composition as set forth in any one of claims 1 to 7 to one surface of a silicon wafer through screen printing;

(2) an adhesion layer forming step of heating the liquid resin composition applied in the step (1) at 60 to 200° C. for 1 min to 3 hours to bring the liquid resin composition to a B stage, and forming an adhesion layer having a thickness of not larger than 200 μm and a surface arithmetic mean roughness of not larger than 2 μm;

(3) a bonding step of bonding a silicon wafer to a dicing tape through said adhesion layer;

(4) a chipping step of cutting an adhesion layer-containing silicon wafer prepared in the step (3) into multiple individual pieces;

(5) a mounting step of peeling an adhesion layer-containing semiconductor chip obtained in the step (4) from the dicing tape, and mounting said semiconductor chip on a lead frame through the adhesion layer of said semiconductor chip; and

(6) a curing step of curing the liquid resin composition on the lead frame.

[9]

The silicon chip die attaching method according to [8], wherein an average particle diameter of said scale-shaped inorganic filler as the component (E) of the liquid resin composition is 0.05 to 15 μm when a mask for screen printing in the step (1) has not less than 40, but less than 300 meshes per inch.

[10]

The silicon chip die attaching method according to [8], wherein an average particle diameter of said scale-shaped inorganic filler as the component (E) of the liquid resin composition is 0.05 to 10 μm when a mask for screen printing in the step (1) has not less than 300, but less than 400 meshes per inch.

[11]

The silicon chip die attaching method according to [8], wherein an average particle diameter of said scale-shaped inorganic filler as the component (E) of the liquid resin composition is 0.05 to 5 μm when a mask for screen printing in the step (1) has 400 to 500 meshes per inch.

[12]

A semiconductor device having a cured product of the liquid resin composition as set forth in any one of [1] to [7].

The liquid resin composition of the invention can be applied to a silicon wafer by a thickness of several μm to several tens of μm through screen printing, without causing irregularities on surface. Further, the liquid resin composition of the invention can easily form the B stage condition when heated. Furthermore, the liquid resin composition of the invention is a type of resin composition that can maintain the B stage condition at room temperature for a long period of time, has a superior adhesiveness to a dicing tape, and exhibits excellent dicing properties when dividing the silicon wafer. In addition, the liquid resin composition of the invention is superior in adhesion to a lead frame, and is thus suitable as a die bonding agent for use in a semiconductor package where a lead frame and a chip are bonded to each other through a minute area.

### DETAILED DESCRIPTION OF THE INVENTION

### (A) Epoxy Resin

There are no particular restrictions on an epoxy resin used in the present invention, as long as the epoxy resin has not less than two epoxy groups in one molecule. In fact, any known epoxy resin having not less than two epoxy groups in one molecule may be used. Specific examples of such epoxy resin include a novolac-type epoxy resin; a bisphenol-type epoxy resin; a biphenyl-type epoxy resin; a phenol aralkyl-type epoxy resin; a dicyclopentadiene-type epoxy resin; a naphthalene-type epoxy resin; an amino group-containing epoxy resin; a later-described silicone-modified epoxy resin; or a mixture of two or more of these epoxy resins. Among these epoxy resins, preferred are a bisphenol A-type resin, a bisphenol F-type resin and a novolac-type epoxy resin, and it is more preferred that such resin(s) be used in combination with a liquid or solid silicone-modified epoxy resin.

One example of the silicone-modified epoxy resin is a copolymer obtained by reacting an alkenyl group-containing epoxy resin and organohydrogenpolysiloxane. Examples of such alkenyl group-containing epoxy resin include those represented by the following formulae (2) to (4).

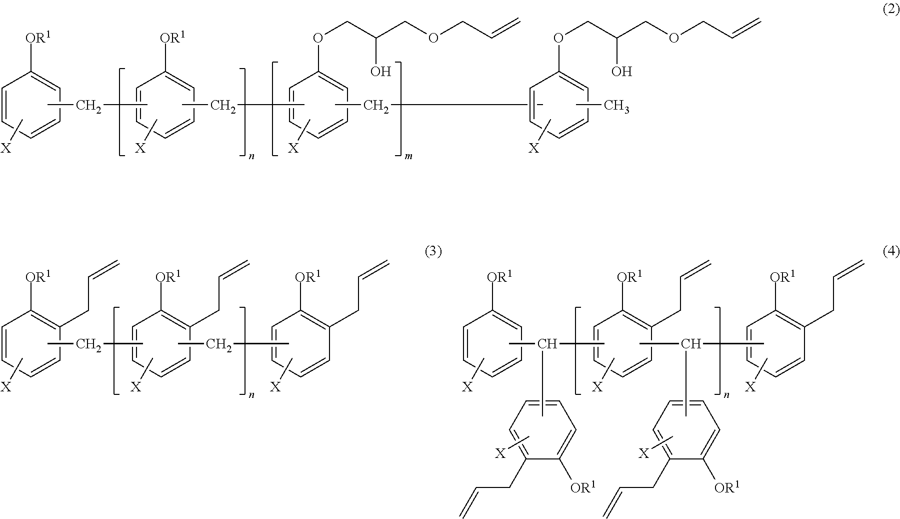

In the above formulae (2) to (4), R¹ represents a glycidyl group (2,3-epoxypropyl group); X represents a hydrogen atom or a bromine atom; n represents an integer of not smaller than 0, preferably 0 to 50, more preferably 1 to 20; and m represents an integer of not smaller than 1, preferably 1 to 5, more preferably 1.

The aforementioned organohydrogenpolysiloxane may be a compound represented by the following average composition formula (5).

Hₐ(R²)_{b}SiO_{(4-a-b)/2} (5)

In the above formula (5), R² represents a substituted or unsubstituted monovalent hydrocarbon group having 1 to 10 carbon atoms; a substituted or unsubstituted hydroxy group; a substituted or unsubstituted alkoxy group having 1 to 10 carbon atoms; or a substituted or unsubstituted alkenyloxy group having 2 to 10 carbon atoms. Examples of such monovalent hydrocarbon group include an alkyl group such as a methyl group, an ethyl group, an n-propyl group, an isopropyl group, an n-butyl group, an isobutyl group, a tert-butyl group, a pentyl group, a neopentyl group, a hexyl group, a cyclohexyl group, an octyl group and a decyl group; an alkenyl group such as a vinyl group, an allyl group, a propenyl group and a butenyl group; an aryl group such as a phenyl group and a tolyl group; an aralkyl group such as a benzyl group and a phenylethyl group; and a halogen-substituted monovalent hydrocarbon group obtained by substituting a part of or all the hydrogen atoms in any of the above hydrocarbon groups with, for example, halogen atoms. Examples of the alkoxy group include a methoxy group, an ethoxy group, a propoxy group, an isopropoxy group and an n-hexyloxy group. Examples of the alkenyloxy group include a vinyloxy group, a propenoxy group and an isopropenoxy group.

a and b are numbers satisfying 0.001≦a≦1, 1≦b≦3, and 1≦a+b≦4; preferably 0.01≦a≦0.1, 1.8≦b≦2, and 1.85≦a+b≦2.1. Such organohydrogenpolysiloxane has 1 to 1,000, preferably 2 to 400, more preferably 5 to 200 silicon atoms in one molecule.

Such organohydrogenpolysiloxane may be a compound represented by the following formula (6).

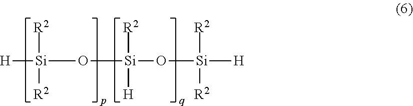

(R² is defined as above, and it is preferred that R² be a methyl group or a phenyl group; p represents an integer of 0 to 1,000, preferably 3 to 400; q represents an integer of 0 to 20, preferably 0 to 5; and p+q satisfies 1<p+q<1,000, preferably 2<p+q<400, more preferably 5<p+q<200)

More specific examples of such organohydrogenpolysiloxane include those represented by the following formulae.

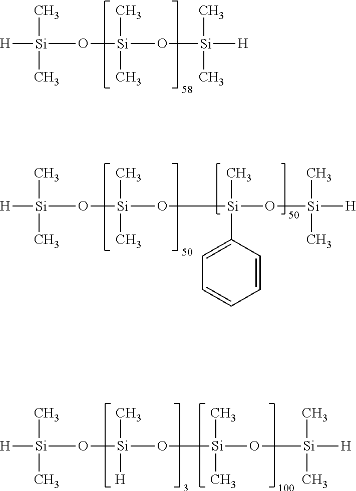

The organohydrogenpolysiloxane has a weight-average molecular weight of 100 to 100,000, preferably 500 to 20,000. When the weight-average molecular weight of the organohydrogenpolysiloxane is within these ranges, there will be observed a uniform structure where the organohydrogenpolysiloxane is uniformly dispersed in the matrix or a sea-island structure where the organohydrogenpolysiloxane forms fine phase separation in the matrix, in accordance with the structure or weight-average molecular weight of the alkenyl group-containing epoxy resin to be reacted with the organohydrogenpolysiloxane.

The uniform structure will be formed when the weight-average molecular weight of the organohydrogenpolysiloxane is relatively low, especially as low as 100 to 10,000. Further, the sea-island structure will be formed when the weight-average molecular weight of the organohydrogenpolysiloxane is relatively high, especially as high as 10,000 to 100,000. There may be selected either the uniform structure or the sea-island structure according to the intended use. It is not preferable when the weight-average molecular weight of the organohydrogenpolysiloxane is lower than 100, because a cured product obtained will become rigid and brittle. It is also not preferable when the weight-average molecular weight of the organohydrogenpolysiloxane is higher than 100,000, because the sea-island structure will become large, and a local stress will thus occur in the cured product obtained.

Here, the weight-average molecular weight refers to a weight-average molecular weight measured by gel permeation chromatography (GPC) under the following conditions, using polystyrene as a standard substance.

Measurement condition
Developing solvent: THF
Flow rate: 200 mL/min
Detector: differential refractive index detector (RI)
Column: TSKGEL SUPERHZ 2000, 3000 and 4000 by TOSOH CORPORATION (each of which was used)
GPC device: HLC-8220GPC
Column temperature: 40° C.
Sample injection volume: 5 (THF solution with concentration of 0.2 weight %)

There may be used a known method for reacting the alkenyl group-containing epoxy resin and the organohydrogenpolysiloxane. For example, there may be used a method where the alkenyl group-containing epoxy resin and the organohydrogenpolysiloxane are reacted through addition reaction under the presence of a platinum-based catalyst. In this way, the silicone-modified epoxy resin can be obtained. The organohydrogenpolysiloxane is preferably copolymerized by an amount at which the SiH groups in the organohydrogenpolysiloxane will be in an amount of 0.1 to 1 mol with respect to 1 mol of the alkenyl groups in the alkenyl group-containing epoxy resin.

### (B) Curing Agent

There are no particular restrictions on a curing agent used in the present invention, as long as the curing agent is a compound having, in one molecule, not less than two functional groups reactive with epoxy groups. Examples of such curing agent include a phenolic resin, an acid anhydride and amines among which a phenolic resin is preferred. Examples of such phenolic resin include those of an aralkyl type, a novolac type, a bisphenol type, a tris (hydroxyphenyl) methane type, a naphthalene type, a cyclopentadiene type and a phenol aralkyl type. Each of these phenolic resins may be used singularly, or two or more of them may be mixed together before use. Particularly, preferred are those of an aralkyl type, a novolac type and a bisphenol type, and it is preferred that these phenolic resins be used in combination with a silicone-modified phenolic resin.

The silicone-modified phenolic resin in the present invention is a copolymer obtained by reacting the organohydrogenpolysiloxane represented by the above formula (5) and an alkenyl group-containing phenolic resin(s) shown below. A known method may be used to perform such reaction. For example, the silicone-modified phenolic resin may be produced by reacting the alkenyl group-containing phenolic resin and the organohydrogenpolysiloxane through addition reaction under the presence of a platinum-based catalyst. The organohydrogenpolysiloxane is preferably copolymerized by an amount at which the SiH groups in the organohydrogenpolysiloxane will be in an amount of 0.1 to 1 mol with respect to 1 mol of the alkenyl groups in the alkenyl group-containing phenolic resin.

Examples of the alkenyl group-containing phenolic resin are as follows.

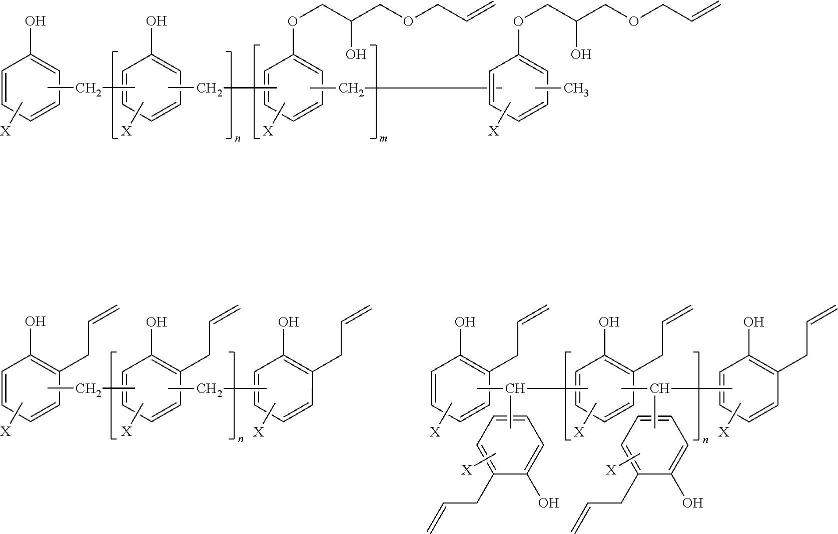

(X, n and m are defined as in formulae (2) to (4))

It is preferred that the component (B) be added in an amount at which the groups in the component (B) that are reactive with epoxy groups will be in an amount of 0.8 to 1.25, more preferably 0.9 to 1.1 equivalents with respect to 1 equivalent of the epoxy groups in the component (A). When the amount of the component (B) added is outside these ranges, a part of the resin composition may remain uncured, and the performances of the cured product and a semiconductor device may thus be impaired.

Particularly, a resin composition containing the silicone-modified epoxy resin and/or the silicone-modified phenolic resin has a function of avoiding repellent on a wafer. Therefore, it is preferred that at least one of the components (A) and (B) of the liquid resin composition of the invention be partially modified by silicone. It is preferred that the silicone-modified epoxy resin and/or the silicone-modified phenolic resin be added in an amount of 0.5 to 5 parts by mass, more preferably 1 to 3 parts by mass, with respect to a total of 100 parts by mass of the components (A) and (B). It is preferable when the amount of the silicone-modified epoxy resin and/or the silicone-modified phenolic resin added is within these ranges, because the resin composition can be uniformly applied to a silicon wafer without being repelled therefrom when performing screen printing.

### (C) Acrylic Resin

An acrylic resin is added to improve an adhesion of the composition to a silicon chip(s) and an adherend(s) when the composition is in B stage, taking advantage of the fact that acrylic resins have low glass-transition temperatures. Such acrylic resin may be a copolymer of a polymer such as acrylic acid ester, methacrylate ester and acrylonitrile; and a monomer. In the present invention, preferred is an acrylic acid ester copolymer having a functional group(s) such as an epoxy group, a carboxyl group, a hydroxyl group and an amide group. By having these functional groups, cross-linking reactions with the components (A) and (B) progress such that a toughness of the heat cured product and the adhesion of the composition to an adherend(s) will be improved.

It is preferred that the acrylic resin be added in an amount of 5 to 900 parts by mass, particularly preferably 10 to 800 parts by mass, with respect to 100 parts by mass of the components (A) and (B). When the acrylic resin is added in an amount of not larger than 5 parts by mass, the resin composition will become brittle in B stage in a way such that a failure of resin composition chipping may occur when dividing a silicon wafer into chips. Further, when the acrylic resin is added in an amount of not smaller than 900 parts by mass, the adhesion of the heat-cured resin composition will be impaired in a way such that the reliably of a device or the like may be impaired as well.

The weight-average molecular weight of the above acrylic resin is 100,000 to 1,000,000, preferably 200,000 to 700,000. When the weight-average molecular weight of the acrylic resin is lower than 100,000, the resin composition will become brittle in B stage in a way such that the failure of resin composition chipping may occur when dividing a silicon wafer into chips. It is not preferable when the weight-average molecular weight of the acrylic resin is higher than 1,000,000, because stringing will occur as a screen mask is separated from a material to be printed (silicon wafer) when performing screen printing, which will then lead to surface roughness of a printed material and void entrainment thereon.

Here, the weight-average molecular weight refers to a weight-average molecular weight measured by gel permeation chromatography (GPC) under the following conditions, using polystyrene as a standard substance.

Measurement condition
Developing solvent: THF
Flow rate: 200 mL/min
Detector: differential refractive index detector (RI)
Column: TSKGEL SUPERHZ 2000, 3000 and 4000 by TOSOH CORPORATION (each of which was used)
GPC device: HLC-8220GPC
Column temperature: 40° C.
Sample injection volume: 5 μL (THF solution with concentration of 0.2 weight %)

### (D) Curing Accelerator

There are no particular restrictions on a curing accelerator (D), as long as it is capable of accelerating a reaction(s) between the epoxy resin (A) and the curing agent (B). Specifically, there may be used, for example, basic organic compounds such as organic phosphorous compounds, imidazoles and tertiary amines. Examples of such organic phosphorous compounds include organic phosphines such as triphenylphosphine, tributylphosphine, tri (p-toluyl) phosphine, tri (p-methoxyphenyl) phosphine and tri (p-ethoxyphenyl) phosphine; a triphenylphosphine-triphenylborate derivative; and a tetraphenylphosphine.tetraphenylborate derivative. Examples of the imidazoles include 2-methylimidazole, 2-ethylimidazole, 2-ethyl-4-methylimidazole, 2-phenylimidazole, 2-phenyl-4-methylimidazole, 2-phenyl-4-methyl-5-hydroxymethylimidazole and 2-phenyl-4,5-dihydroxymethylimidazole. Examples of the tertiary amines include triethylamine, benzyldimethylamine, α-methylbenzyldimethylamine and 1,8-diazabicyclo [5.4.0] undecene-7.

Particularly, preferred is a tetraphenylphosphine.tetraphenylborate derivative represented by the following formula (7), or a methylolimidazole derivative represented by the following formula (8). It is preferred that these curing accelerators be selected in combination with the curing agent (B).

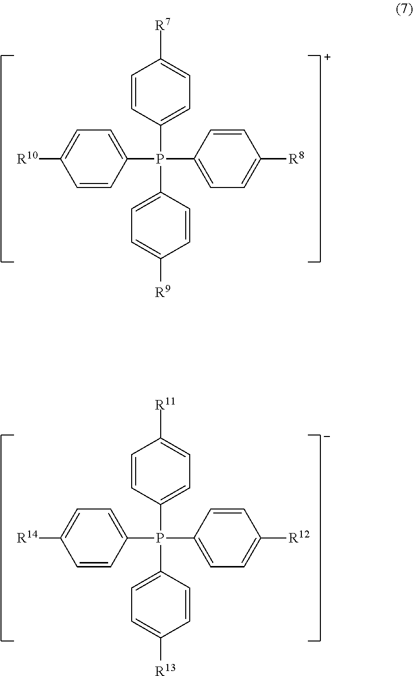

(Each of R⁷ to R¹⁴ independently represents a hydrogen atom, a monovalent hydrocarbon group having 1 to 10 carbon atoms or a halogen atom.)

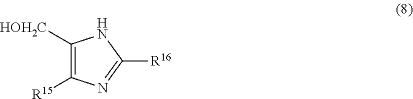

(R¹⁵ represents a methyl group or a methylol group; and R¹⁶ represents a monovalent hydrocarbon group having 1 to 10 carbon atoms.)

The curing accelerator (D) is added in an amount of 0.05 to 10 parts by mass, preferably 0.1 to 10 parts by mass, more preferably 0.2 to 5 parts by mass, with respect to the total of 100 parts by mass of the components (A) and (B). When the curing accelerator is in an amount of smaller than such lower limits, the epoxy resin composition may be cured in an insufficient manner. Further, when the curing accelerator is in an amount of greater than such upper limits, the storability of the epoxy resin composition or a stability thereof in B stage may be impaired.

### (E) Inorganic Filler

An inorganic filler is added to reduce a thermal expansion coefficient and improve a resin strength. Such inorganic filler may have a spherical shape or a pseudospherical shape, or even a scalelike shape.

It is preferred that the spherical or pseudospherical inorganic filler have an average particle diameter of 0.05 to 5 μm, particularly preferably 0.3 to 3 μm. In this specification, the average particle diameter of the spherical or pseudospherical inorganic filler refers to a particle diameter (D50) corresponding to a cumulative mass percentage of 50% in a particle size distribution measured by laser diffraction scattering method. When the average particle diameter of the spherical or pseudospherical inorganic filler is smaller than the above lower limits, the viscosity of the resin composition will rise in a way such that a printability will worsen. Further, it is not preferable when the average particle diameter of the spherical or pseudospherical inorganic filler is greater than the above upper limits, because a surface roughness in B stage will become significant in a way such that an adhesion to a dicing film will be impaired, and that chip flying and/or chip chipping may thus occur when performing dicing.

It is desired that the maximum particle diameter of the spherical or pseudospherical inorganic filler be not larger than 50%, particularly desirably not larger than 30%, of the thickness of a die bonding agent (normally about 10 to 50 μm) applied to a wafer. When such maximum particle diameter is larger than the above upper limits, a chip, a substrate or wiring, for example, may be damaged, or the functions of a semiconductor device may be impaired as a local stress occurs on an boundary between the inorganic filler and the rest part. Meanwhile, no restrictions are imposed on a lower limit of such maxim particle diameter. Here, the maximum particle diameter can also be measured by the above laser diffraction scattering method.

Examples of the spherical or pseudospherical inorganic filler include a molten silica, a crystalline silica, alumina, titanium oxide, silica titania, boron nitride, aluminum nitride, silicon nitride, magnesia and magnesium silicate. Any of these inorganic fillers may be used singularly, or two or more of them may be used in combination. It is especially preferred that any one of silica and alumina be used singularly, or that the two be used in combination.

Further, the “scalelike shape” refers to a shape other than a fibrous shape, a needle-like shape and a granular shape. Specifically, scale-shaped particles are particles having an average thickness t of 0.005 to 5 μm, preferably 0.05 to 2 μm; an average particle diameter a of 0.05 to 15 μm, preferably 0.1 to 10 μm; and an aspect ratio (average particle diameter a/average thickness t) of 2 to 100, preferably 4 to 70.

Further, in this specification, the average thickness t of the scale-shaped inorganic filler is obtained as follows. That is, at least 100 pieces of the scale-shaped inorganic filler are drawn, followed by using a scanning microscope (SEM) to measure the thicknesses thereof, and then calculating an average value by dividing the sum of such thicknesses by the number of the pieces measured. Furthermore, in this specification, the average particle diameter a of the scale-shaped inorganic filler refers to a particle diameter (D50) corresponding to a cumulative mass percentage of 50% in a particle size distribution measured by laser diffraction scattering method. The aspect ratio refers to a value obtained by dividing the value of the average particle diameter a by the value of the average thickness t.

It is preferred that the liquid resin composition of the invention be applied when performing screen printing. If used in screen printing, it is preferred that the average particle diameter of the scale-shaped inorganic filler be 0.05 to 15 μm when a mask for screen printing has not less than 40, but less than 300 meshes per inch; 0.05 to 10 μm when the mask for screen printing has not less than 300, but less than 400 meshes per inch; and 0.05 to 5 μm when the mask for screen printing has not less than 400, and not more than 500 meshes per inch.

Examples of the scale-shaped inorganic filler include talc, mica, a molten silica, a crystalline silica, alumina, titanium oxide, silica titania, boron nitride, aluminum nitride, silicon nitride, magnesia and magnesium silicate. Any of these inorganic fillers may be used singularly, or two or more of them may be used in combination. It is especially preferred that any one of talc and mica be used singularly, or that the two be used in combination.

As for the ratios of the spherical or pseudospherical inorganic filler and the scale-shaped inorganic filler in the inorganic filler, the spherical or pseudospherical inorganic filler is in an amount of 10 to 90% by mass with respect to 100% by mass of the inorganic filler, and the scale-shaped inorganic filler is also in an amount of 10 to 90% by mass with respect to 100% by mass of the inorganic filler. Preferably, the spherical or pseudospherical inorganic filler is in an amount of 20 to 80% by mass with respect to 100% by mass of the inorganic filler, and the scale-shaped inorganic filler is also in an amount of 20 to 80% by mass with respect to 100% by mass of the inorganic filler. More preferably, the spherical or pseudospherical inorganic filler is in an amount of 30 to 60% by mass with respect to 100% by mass of the inorganic filler, and the scale-shaped inorganic filler is in an amount of 40 to 70% by mass with respect to 100% by mass of the inorganic filler. When the spherical or pseudospherical inorganic filler is in an amount of greater than 90% by mass with respect to 100% by mass of the inorganic filler, an adhesion to a lead frame weakens in a way such that failures may occur in the later-described moisture and solder resistance test or temperature cycle test. Meanwhile, when the scale-shaped inorganic filler is in an amount of greater than 90% by mass with respect to 100% by mass of the inorganic filler, thixotropy will increase in a way such that leveling after printing will become difficult. As a result, a surface roughness after B stage will become more significant, and an adhesion to a dicing tape will thus be impaired, which will then lead to chip flying and/or chip chipping when performing dicing in certain cases.

The inorganic filler is added in an amount of 50 to 600 parts by mass, preferably 60 to 300 parts by mass, more preferably 70 to 150 parts by mass, with respect to the total of 100 parts by mass of the epoxy resin (A) and the curing agent (B). When such inorganic filler is added in an amount smaller than these lower limits, the resin strength and adhesion after curing will weaken in a way such that failures may occur in the later-described moisture and solder resistance test or temperature cycle test. Further, when such inorganic filler is added in an amount of greater than these upper limits, a viscosity exhibited at the time of performing die attach will increase in a way such that it may be difficult to bond a chip(s) to a substrate.

Further, it is preferred that the inorganic filler be surface treated by a silane coupling agent in advance. More preferably, it is desired that the epoxy resin (A) and such inorganic filler that has been surface treated by a silane coupling agent be kneaded under a reduced pressure in advance. In this way, the surface of the inorganic filler and the interface of the epoxy resin can be in a substantially wet condition such that a moisture resistance reliability can be dramatically improved.

Examples of the above silane coupling agent include γ-glycidoxypropyltrimethoxysilane, γ-glycidoxypropylmethyldiethoxysilane, γ-glycidoxypropyltriethoxysilane, p-styryltrimethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, γ-acryloxypropyltrimethoxysilane, N-β (aminoethyl) γ-aminopropylmethyl dimethoxysilane, N-β (aminoethyl) γ-aminopropyltrimethoxysilane, N-β (aminoethyl) γ-aminopropyltriethoxysilane, γ-aminopropyltrimethoxysilane, γ-aminopropyltriethoxysilane, N-phenyl-γ-aminopropyltrimethoxysilane, γ-mercaptopropylmethyldimethoxysilane, γ-mercaptopropyltrimethoxysilane, bis (triethoxypropyl) tetrasulfide and γ-isocyanatepropyltriethoxysilane. Any of these silane coupling agents may be used singularly, or two or more of them may be used in combination. Among these silane coupling agents, it is preferred that γ-glycidoxypropyltrimethoxysilane be used.

The silane coupling agent(s) are added in an amount of 0.1 to 5 parts by mass, preferably 0.3 to 3 parts by mass, with respect to a total of 100 parts by mass of the components (A) to (E).

### (F) Diluent

A diluent (F) is added to control the viscosity of the resin composition. As such component (F), one kind of diluent may be used singularly, or two or more kinds of diluent may be used in combination. There are no particular restrictions on the kind of a diluent, as long as the diluent is in liquid form at normal temperature. Preferred is a solvent with a boiling point of 150° C. or higher, that is capable of dissolving a mixture of the components (A), (B) and (C), but incapable of dissolving the components (D) and (E). Specific examples of such diluent include an aromatic hydrocarbon such as toluene and xylene; a ketone such as methylisobutyl ketone, cyclohexanone, isophorone and diacetone alcohol; a glycol ether such as methyl cellosolve, ethyl cellosolve, butyl cellosolve, methyl carbitol, ethyl carbitol and butyl carbitol; and a glycol ester such as methyl cellosolve acetate, ethyl cellosolve acetate and carbitol acetate.

It is preferred that such diluent have a moderately high boiling point e.g. 180 to 260° C., in terms of achieving a workable and favorable viscosity of the resin composition in printing steps. Specific examples of a diluent with such boiling point include isophorone, ethyl carbitol, butyl carbitol, carbitol acetate, butyl carbitol acetate, dipropyleneglycol dimethylether, dipropyleneglycol n-propyl ether, dipropyleneglycol n-butyl ether, dipropyleneglycol methylether, tripropyleneglycol methyl ether, dipropyleneglycol methylether acetate, 1,3-butyleneglycol diacetate and 1,6-hexanediol diacetate.

Although there are no particular restrictions on the amount of the diluent added, it is added in an amount of 10 to 900 parts by mass, preferably 30 to 800 parts by mass, with respect to a total of 100 parts by mass of the epoxy resin (A), curing agent (B), thermoplastic resin (C) and curing accelerator (D). It is not preferable when the diluent is added in an amount of larger than 900 parts by mass, because the resin composition will exhibit an extremely low viscosity in a way such that the inorganic filler (E) may precipitate while stored for a long period of time. Meanwhile, when the diluent is added in an amount of smaller than 10 parts by mass, the viscosity of the resin composition will increase in a way such that it may be difficult to apply the resin composition to a silicon wafer.

### (G) Dimethyl Silicone

Since dimethyl silicone has a low surface tension, it has an effect of swiftly leveling mesh marks left after performing screen printing; and an effect of defoaming voids that occur after printing. Such dimethyl silicone is added in an amount of 0.01 to 2 parts by mass, preferably 0.1 to 1 parts by mass, with respect to the total of 100 parts by mass of the epoxy resin (A) and curing agent (B). When the dimethyl silicone is added in an amount of larger than 2 parts by mass, the compatibility between the component (A) and component (B) will be impaired in a way such that they may be separated from each other. When the dimethyl silicone is added in an amount of smaller than 0.01 parts by mass, there may not be achieved a sufficient leveling effect and defoaming effect.

The viscosity of such dimethyl silicone is measured by a single cylinder-type rotary viscometer at 25° C., in accordance with the method described in JIS Z 8803:2011. It is preferred that such viscosity be 1 to 1,000,000 mPa·s, more preferably 10 to 100,000 mPa·s. When this viscosity is within these ranges, there will not be observed an extremely low boiling point in a way such that the dimethyl silicone will hardly volatilize in production steps. Therefore, a dispersibility will not be undermined, and a sufficient leveling effect and defoaming effect can thus be achieved easily. It is preferred that n in the following general formula (9) represent a value capable of leading to the above viscosities.

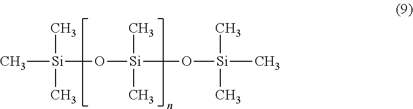

(In the above formula, n represents an integer of 0 to 2,000.)

Other than the abovementioned components, there may also be added to the invention, for example, an insulating filler such as silica, alumina, talc, mica, silicon nitride and boron nitride; a silane coupling agent; a flame retardant; an ion trapping agent; a wax; a coloring agent; and an adhesion aid, depending on the intended use and by an amount(s) not thwarting the objectives of the invention.

### Production Method of Liquid Resin Composition

The liquid resin composition of the invention can be produced by mixing the components (A) to (G) through a known method. For example, the components (A) to (G) may be mixed by a mixer, a roll mill and the like. When using the inorganic filler (E) that has been surface treated by a silane coupling agent, it is preferred that the epoxy resin (A) and the inorganic filler surface treated by the silane coupling agent be kneaded under a reduced pressure in advance.

### Liquid Resin Composition in B Stage

It is preferred that the liquid resin composition of the invention be able to reach B stage after a specimen thereof having any thickness from 5 to 200 μm has been heated at 60 to 200° C., preferably 80 to 150° C., for 1 min to 3 hours, preferably 10 min to 1 hour. Further, it is preferred that an arithmetic mean roughness of the liquid resin composition of the invention in B stage be not larger than 2 μm (0 to 2 μm), more preferably not larger than 1 μm (0 to 1 μm). Here, such arithmetic mean roughness can be measured in accordance with JIS B0601:2013. It is preferable when the arithmetic mean roughness is within these ranges, because the adhesion to a dicing tape; and a film thickness of an adhesive agent layer after bonding a semiconductor chip(s) to a lead frame will become stable.

It is desired that the viscosity of the liquid resin composition of the invention in B stage be 200 to 100,000 Pas in terms of a value of a lowest melt viscosity. In the present invention, the lowest melt viscosity is obtained as follows. That is, the viscosity of the composition is continuously measured as the temperature rises from 50 to 200° C. at a rate of 5° C./min, using a parallel plate-type viscoelasticity measuring device (MR-300 by Rheology Co., Ltd.). There, the lowest value measured is defined as a measured value of the lowest melt viscosity. It is not preferable when the lowest melt viscosity is beyond the above range, because a wettability between the liquid resin composition and an adherend(s) at the time of performing die attach will be impaired, which will then lead to voids and adhesion failures. It is also not preferable when the lowest melt viscosity is below the above lower limit, because the liquid resin composition will exhibit an extremely high fluidity at the time of performing die attach, in a way such that the liquid resin composition will flow out from the side surface(s) of an Si chip, which will then, for example, contaminate the peripheral region of the chip and makes it difficult to perform gap control between the chip and the adherend(s).

It is preferred that the liquid resin composition of the invention exhibit a thixotropic index of 0.8 to 1.5, more preferably 0.9 to 1.3. In the present invention, the thixotropic index is obtained as follows. That is, under a temperature of 25° C., an E-type viscometer (HBDV-III by Brookfield AMETEK) is used to measure both the viscosities of the composition at a shear rate of 0.2 (sec⁻¹) and at a shear rate of 2.0 (sec⁻¹) in accordance with JIS Z8803:2011, each viscosity being measured 2 min after rotation has started. A value obtained through the following calculation formula is then defined as the thixotropic index. It is preferable when the thixotropic index is within the above ranges, because there can be achieved a favorable leveling property of the resin surface after performing screen printing, in a way such that a surface roughness after reaching B stage will become insignificant.

Thixotropic index (T.I.)=(Viscosity at shear rate of 0.2 sec⁻¹ [Pa·s])/(Viscosity at shear rate of 2.0 sec⁻¹ [Pa·s])

### Method for Using Liquid Resin Composition

The liquid resin composition of the invention can be used by a process including the following steps (1) to (6).

### (1) Liquid Resin Composition Coating Step

The liquid resin composition is applied to a silicon wafer through screen printing. The surface of the silicon wafer to which the liquid resin composition is to be applied is a surface that will adhere to a lead frame after performing dicing to obtain a semiconductor chip(s).

### (2) Adhesion Layer Forming Step

An adhesion layer is formed as the liquid resin composition applied in step (1) is brought to B stage after being heated at 60 to 200° C. for 1 min to 3 hours. This adhesion layer has a thickness of not larger than 200 μm, and a surface arithmetic mean roughness of not larger than 2 μm.

### (3) Bonding Step

The silicon wafer is to be bonded to a dicing tape through the adhesion layer. The silicon wafer may be bonded to the dicing tape through a known method, and there may be used a known dicing tape.

### (4) Chipping Step

Semiconductor chips are obtained by cutting an adhesion layer-containing silicon wafer prepared in step (3) into multiple individual pieces. As for a cutting method, the adhesion layer-containing silicon wafer may be cut into multiple individual pieces with the silicon wafer and the adhesion layer being tightly bonded to each other, through a dicing method where a silicon wafer is cut by a diamond blade or, for example, through a laser dicing method. The cutting method may be appropriately selected depending on the intended use.

### (5) Mounting Step

Each adhesion layer-containing semiconductor chip thus obtained through dicing is peeled from the dicing tape, and then mounted on a lead frame through the chip's adhesion layer. Such semiconductor chip may be mounted by a method using a die bonder. Further, there are no particular restrictions on the conditions under which the semiconductor chip is mounted. In fact, such conditions may be appropriately selected depending on the intended use. Examples of such conditions include a temperature and time for performing preheat immediately before mounting the semiconductor chip; a temperature and pressure under which the semiconductor chip is mounted on the lead frame; and a time for which the semiconductor chip and the lead frame are exposed to such temperature and pressure. Preheat is performed to improve the adhesiveness between the adhesion layer and the silicon wafer, and it is preferred that preheat be performed at 50 to 150° C. for 2 sec to 10 min. It is preferred that the semiconductor chip be mounted on the lead frame under conditions of semiconductor chip temperature: 25 to 250° C./temperatures of substrate and other chip(s): 25 to 200° C./time: 0.1 to 10 sec/pressure: 0.01 to 10 MPa.

### (6) Curing Step

The liquid resin composition on the lead frame is cured. As for a method for curing the liquid resin composition, the liquid resin composition may be cured using, for example, an openable or continuous oven. The liquid resin composition is cured at 100 to 200° C., preferably 120 to 180° C., for 1 to 8 hours, preferably 1.5 to 3 hours. Particularly, a conductive resin composition may be cured at the same time in a resin encapsulation step of a semiconductor device.

### Working Example

The present invention is described in greater detail hereunder with reference to working examples. However, the present invention is not limited to the following working examples.

### Synthetic Example 1

### Synthesis of Silicone-Modified Epoxy Resin

An epoxy resin represented by the following formula (10) (weight-average molecular weight: 2,500 in terms of polystyrene) of 149 g and toluene of 298 g were put into a flask equipped with stirring blades, a drip funnel, a thermometer, an ester adapter and a reflux tube, followed by performing azeotropic dehydration at 130° C. for 2 hours. A product thus obtained was cooled to 100° C., and a catalyst (CAT-PL-50T by Shin-Etsu Chemical Co., Ltd.) of 1 g was then delivered by drops thereinto. Upon completing delivering the catalyst in such manner, 30 min was spent in delivering thereinto by drops a mixture of 68 g (0.023 mol) of an organohydrogenpolysiloxane represented by the following formula (11) and 136 g of toluene. A product thus obtained was then left to react at 100° C. for 6 hours. Toluene was then removed from a reactant mixture thus obtained under a reduced pressure, thus obtaining a silicone-modified epoxy resin represented by the following formula (12). The weight-average molecular weight of this composition was 20,000 (in terms of polystyrene), and the composition contained organopolysiloxane by an amount of 31.2 weight %.

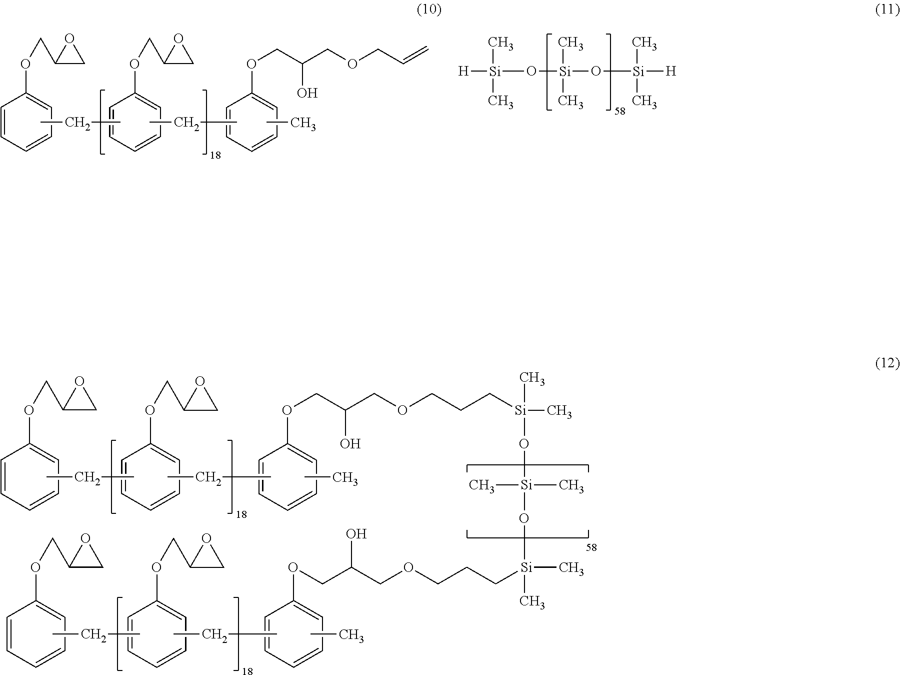

### Working Examples 1 to 13, Comparative Examples 1 to 15

The following components were mixed in amounts shown in Table 1 and Table 2, using a planetary mixer. A mixture thus obtained was then passed through a triple roll mill, followed by performing mixing again at 25° C. using the planetary mixer. In this way, there were obtained liquid resin compositions of working examples 1 to 13 and comparative examples 1 to 15. With regard to working examples 9 to 13 and comparative examples 8 to 15 that are shown in Table 2, although each composition was prepared at a composition ratio of working example 1 shown in Table 1, the average particle diameters of the spherical filler and the average thicknesses of the scale-shaped filler were different from those of working example 1.

### (A) Epoxy Resin

(1) Epoxy resin (a1): Silicone-modified epoxy resin obtained in synthetic example 1 (epoxy equivalent 291, softening point 70° C., solid at room temperature (25° C.))

(2) Epoxy resin (a2): o-cresol novolac type epoxy resin (EOCN1020-55 by Nippon kayaku Co., Ltd., epoxy equivalent 200, softening point 57° C., solid at room temperature (25° C.))

(3) Epoxy resin (a3): Bisphenol A-type epoxy resin (RE310S by Nippon kayaku Co., Ltd., epoxy equivalent 180, liquid (viscosity 15 Pa·s) at room temperature (25° C.))

### (B) Curing Agent

(1) Curing agent (b1): Aralkyl-type phenolic resin (MEHC-7800H by MEIWA PLASTIC INDUSTRIES, LTD., phenol equivalent 175, softening point 85° C., solid at room temperature (25° C.))

(2) Curing agent (b2): diallyl bisphenol A (BPA-CA by KONISHI CHEMICAL IND CO., LTD., phenol equivalent 154, liquid (viscosity 16 Pa·s) at room temperature (25° C.))

### (C) Thermoplastic Resin

Glycidyl group-containing acrylic acid ester copolymer (SG-80H (without methylethylketone) by Nagase ChemteX Corporation, molecular weight 350,000)

### (D) Curing Accelerator

2-phenyl-4-methyl-5-hydroxymethylimidazole (2P4MHZ-PW by SHIKOKU CHEMICALS CORPORATION.)

### (E) Inorganic Filler

### (E1) Spherical Inorganic Filler

(1) Spherical inorganic filler (E1-1): Silica (AEROSIL 90 by NIPPON AEROSIL CO., LTD., spherical, average particle diameter 0.02 μm)

(2) Spherical inorganic filler (E1-2): Silica (SO-25R by Admatechs, spherical, average particle diameter 0.5 μm)

(3) Spherical inorganic filler (E1-3): Silica (N-MSR04 by TATSUMORI LTD., spherical, average particle diameter 4 μm)

(4) Spherical inorganic filler (E1-4): Alumina (AO-41R by Admatechs, spherical, average particle diameter 10 μm)

### (E2) Scale-Shaped Inorganic Filler

(5) Scale-shaped inorganic filler (E2-1): Talc (FH104 by FUJI TALC INDUSTRIAL CO., LTD., scale-shaped, average thickness 0.2 μm, average particle diameter 4 μm, aspect ratio 20)

(6) Scale-shaped inorganic filler (E2-2): Talc (FH108 by FUJI TALC INDUSTRIAL CO., LTD., scale-shaped, average thickness 0.2 μm, average particle diameter 8 μm, aspect ratio 40)

(7) Scale-shaped inorganic filler (E2-3): Talc (MG115 by FUJI TALC INDUSTRIAL CO., LTD., scale-shaped, average thickness 0.2 μm, average particle diameter 14 μm, aspect ratio 70)

(8) Scale-shaped inorganic filler (E2-4): Talc (RL119 by FUJI TALC INDUSTRIAL CO., LTD., scale-shaped, average thickness 0.2 μm, average particle diameter 17 μm, aspect ratio 85)

Before use, these inorganic fillers were surface treated by γ-glycidoxypropyltrimethoxysilane as a silane coupling agent (KBM-403 by Shin-Etsu Chemical Co., Ltd.).

### (F) Diluent

Solvent: Diethyleneglycol monoethylether (EDGAC by Daicel Corporation)

### (G) Dimethyl Silicone

KF-96-100cs (by Shin-Etsu Chemical Co., Ltd., viscosity 97 mPa·s at 25° C.)

The later-described evaluation tests were performed on each liquid resin composition. The results thereof are shown in Table 1 and Table 2.

### Viscosity

The viscosity of each liquid resin composition obtained in working and comparative examples was measured as follows. Specifically, under a temperature of 25° C., an E-type viscometer (HBDV-III by Brookfield AMETEK) was used to measure both the viscosities of the composition at a shear rate of 0.2 (sec⁻¹) and at a shear rate of 2.0 (sec⁻¹) in accordance with JIS Z8803:2011, each viscosity being measured 2 min after rotation has started. Thixotropic indexes were then obtained through the following calculation formula, and are shown in Table 1 and Table 2.

Thixotropic index (T.I.)=(Viscosity at shear rate of 0.2 sec⁻¹ [Pa·s])/(Viscosity at shear rate of 2.0 sec⁻¹ [Pa·s])

### Lowest Melt Viscosity in B Stage

Each liquid resin composition reached B stage after being heated at 120° C. for 15 min, and a specimen thereof having a thickness of 1 mm was prepared. The viscosity of such specimen was continuously measured as the temperature rose from 50 to 200° C. at a rate of 5° C./min, using a parallel plate-type viscoelasticity measuring device (MR-300 by Rheology Co., Ltd.). There, the lowest value was defined as the lowest melt viscosity. The results thereof are shown in Table 1 and Table 2.

Remaining Void after Screen Printing

Screen printing was performed in the following manner. That is, a screen mask used had an opening section of a size of 140 mmφ, a thickness of 50 μm and 200 to 400 meshes per inch. Particularly, screen printing was performed on one surface of a silicon wafer (6 inch diameter, 0.2 mm) using each liquid resin composition, under a printing pressure of 10 psi and at an urethane squeegee rate of 25 mm/s. The liquid resin composition was thinly applied to the entire surface of the one surface of the silicon wafer. The following criteria were used to evaluate the number of voids observed immediately after applying the composition to the wafer; and the number of voids observed after such wafer had been left to stand for 30 min under an environment of 25° C./50% RH. The number of voids was counted by observing the voids on the surface of the silicon wafer through a microscope. The results thereof are shown in Table 1 and Table 2.

∘ . . . Less than 10 voids
Δ . . . 11 to 50 voids
x . . . Not less than 51 voids
Surface Arithmetic Mean Roughness after Reaching B Stage

On the liquid resin composition-coated silicon wafer obtained in the test for observing the remaining voids after performing screen printing, the liquid resin composition was allowed to reach B stage under conditions of 120° C./15 min/aeration with nitrogen. A surface arithmetic mean roughness of such liquid resin composition in B stage was measured by a laser microscope (VK-9700 by KEYENCE CORPORATION). The results thereof are shown in Table 1 and Table 2.

### Dicing Property (Chip Flying, Chip Cracking)

A dicing tape (T-80MW by TOYO ADTEC CO., LTD) was bonded to the side of the silicon wafer on which the B-staged liquid resin composition was present, followed by dividing the silicon wafer into 2×2 mm individual pieces at a dicing rate of 50 mm/s, and evaluating dicing properties (chip flying and chip cracking). Examples where chip flying or chip cracking did not occur were marked “∘,” whereas examples where chip flying and/or chip cracking occurred in at least one location were marked “x.” The results thereof are shown in Table 1 and Table 2.

### Dicing Property (Resin Chipping)

The dicing tape (T-80MW by TOYO ADTEC CO., LTD) was bonded to the side of the silicon wafer on which the B-staged liquid resin composition was present, followed by dividing the silicon wafer into 2×2 mm individual pieces at the dicing rate of 50 mm/s, and evaluating a dicing property (resin chipping). The silicon wafer pieces thus obtained through dicing were then picked up from the dicing tape, followed by observing such silicon wafer pieces through an electronic microscope. Here, examples where resin chipping was not observed were marked “∘,” whereas examples where resin chipping was observed were marked “x.” The results thereof are shown in Table 1 and Table 2.

### Adhesion

The 2×2 mm silicon wafer pieces obtained through dicing were picked up from the dicing tape, and then die attached to a Cu lead frame, a nickel/palladium/gold-plated lead frame and an Ag-plated lead frame (100 μm thick, 35×35 mm) through an epoxy composition. Die attaching was performed under a pressure of 2 MPa for 0.5 sec, and the temperatures of the silicon wafer piece(s) and substrate (referred to as device hereunder) were both 150° C. at the time of performing die attaching. Later, the liquid resin composition in B stage (referred to as adhesion layer hereunder) was cured after being heated at 125° C. for an hour, and at 165° C. for another 2 hours. After being cured, the device was left under a condition of 85° C./85 RH % for 168 hours. The device was then passed three times through an IR reflow oven with a maximum temperature of 260° C., followed by measuring a die shear strength of the device at 260° C., and then defining such die shear strength as adhesion strength. Examples exhibiting an adhesion strength of not lower than 1 MPa were marked “∘,” whereas examples exhibiting an adhesion strength of not higher than 1 MPa were marked “x.” The results thereof are shown in Table 1 and Table 2.

### Die Attach Property

The dicing tape (T-80MW by TOYO ADTEC CO., LTD) was bonded to the side of the silicon wafer on which the B-staged liquid resin composition was present, followed by dividing the silicon wafer into 5×5 mm individual pieces at the dicing rate of 50 mm/s. The silicon wafer pieces thus obtained through dicing were picked up from the dicing tape, and then die attached to a nickel/palladium/gold-plated lead frame (100 μm thick, 35×35 mm) through the adhesion layer. Die attaching was performed under a pressure of 2 MPa for 0.5 sec, and the temperature of the device was 150° C. at the time of performing die attaching. Later, the adhesion layer was cured after being heated at 125° C. for an hour, and at 165° C. for another 2 hours. An ultrasonic flaw detector (Quantam 350 by SONIX) was used to observe the existence or non-existence of voids and/or peelings that had occurred in the cured device. Examples where voids and/or peelings were observed in not smaller than 5% of the chip area were marked “x,” whereas examples where voids and/or peelings were observed in smaller than 5% of the chip area were marked “∘.” The results thereof are shown in Table 1 and Table 2.

### Moisture Resistance/Solder Resistance Test

KMC-2520 (epoxy encapsulation material by Shin-Etsu Chemical Co., Ltd.) was further used to encapsulate the device that had been prepared for die attach property observation. Here, molding was performed under conditions of mold temperature: 175° C./injection time: 10 sec/injection pressure: 70 kPa/molding time: 90 sec, and post curing was performed at 180° C. for 2 hours. A specimen obtained after molding had a thickness of 1,000 μm, and a size of 35×35 mm, as a whole. The specimen thus obtained was kept in a thermo-hygrostat of 85° C./85 RH % for 168 hours, and was then passed three times through an IR reflow oven with a maximum temperature of 260° C. Next, an ultrasonic flaw detector was used to observe the existence or non-existence of failures such as peelings in an area of not smaller than 20% and Si chip cracks, and the number of specimens exhibiting such failures (number of specimens exhibiting failures/total number of specimens (20)) was counted. The results thereof are shown in Table 1 and Table 2.

### Temperature Cycle Test

After performing the aforementioned moisture resistance/solder resistance test, specimens exhibiting cracks or the like were put into a temperature cycle tester. Here, a cycle of −55° C./30 min+(−55° C.→125° C.)/5 min+125° C./30 min+(125° C.→−55° C.)/5 min was employed as 1 cycle, and there were repeated 500 cycles. Later, an ultrasonic flaw detector was used to observe the existence or non-existence of failures such as peelings and cracks, and the number of specimens exhibiting such failures (number of specimens exhibiting failures/total number of specimens) was counted. The results thereof are shown in Table 1 and Table 2.

TABLE 1

| | | Working example | | | | | | | | Comparative example | | | | | | |
|---|---|---|---|---|---|---|---|---|---|---|---|---|---|---|---|---|
| Composition (part by mass) | | 1 | 2 | 3 | 4 | 5 | 6 | 7 | 8 | 1 | 2 | 3 | 4 | 5 | 6 | 7 |
| A | Epoxy resin (a 1) | 2 | 2 | 2 | 2 | 2 | 2 | 2 | | 2 | 2 | 2 | 2 | 2 | 2 | |
| | Epoxy resin (a 2) | 52 | 52 | 52 | 52 | 52 | 52 | 52 | | 52 | 52 | 52 | 52 | 52 | 52 | 54 |
| | Epoxy resin (a 3) | | | | | | | | 52 | | | | | | | |
| B | Curing agent (b 1) | 46 | 46 | 46 | 46 | 46 | 46 | 46 | | 46 | 46 | 46 | 46 | 46 | 46 | 46 |
| | Curing agent (b 2) | | | | | | | | 46 | | | | | | | |
| C | Thermoplastic resin | 50 | 50 | 50 | 50 | 50 | 50 | 200 | 200 | | 50 | 50 | 50 | 50 | 50 | 50 |
| D | Curing accelerator | 5 | 5 | 5 | 5 | 5 | 5 | 5 | 5 | 5 | | 5 | 5 | 5 | 5 | 5 |
| E1 | Spherical filler (E1-2) | 50 | 25 | 300 | 10 | 90 | 150 | 20 | 350 | 50 | 50 | 50 | 20 | 350 | 100 | 0 |
| E2 | Scalelike filler (E2-1) | 50 | 25 | 300 | 90 | 10 | 150 | 80 | 150 | 50 | 50 | 50 | 20 | 350 | 0 | 100 |
| F | Diluent | 150 | 150 | 150 | 150 | 150 | 150 | 800 | 900 | 80 | 150 | 150 | 150 | 300 | 150 | 150 |
| G | Dimethyl silicone | 1 | 1 | 1 | 1 | 1 | 1 | 1 | 1 | 1 | 1 | | 1 | 1 | 1 | 1 |
| Other | KBM403 | 1 | 1 | 1 | 1 | 1 | 1 | 1 | 1 | 1 | 1 | 1 | 1 | 1 | 1 | 1 |
| com- | | | | | | | | | | | | | | | | |
| ponent | | | | | | | | | | | | | | | | |
| Eval- | Viscosity (Pa · s) 0.2 rpm | 35 | 20 | 83 | 62 | 18 | 55 | 72 | 53 | 33 | Curing | 32 | 12 | 140 | 20 | 85 |
| uation | Viscosity (Pa · s) 2 rpm | 28 | 18 | 65 | 44 | 16 | 48 | 65 | 43 | 30 | failure | 30 | 12 | 89 | 17 | 44 |
| result | Thixotropic index | 1.2 | 1.1 | 1.3 | 1.4 | 1.1 | 1.2 | 1.1 | 1.2 | 1.1 | | 1.1 | 1.0 | 1.6 | 1.1 | 1.9 |
| | Lowest melt viscosity in | 700 | 450 | 37000 | 770 | 490 | 1400 | 4200 | 15000 | 80 | | 600 | 300 | 50000 | 460 | 580 |
| | B stage(Pa · s) | | | | | | | | | | | | | | | |
| | Number of meshes per | 200 | 200 | 200 | 200 | 200 | 200 | 200 | 200 | 200 | | 200 | 200 | 200 | 200 | 200 |
| | inch of mask used | | | | | | | | | | | | | | | |
| | Void observed immediately | ○ | ○ | ○ | ○ | ○ | ○ | ○ | ○ | ○ | | × | ○ | ○ | ○ | [symbol] |
| | after printing | | | | | | | | | | | | | | | |
| | Void observed 30 min | ○ | ○ | ○ | ○ | ○ | ○ | ○ | ○ | ○ | | × | ○ | ○ | ○ | ○ |
| | after printing | | | | | | | | | | | | | | | |
| | Surface arithmetic | 0.2 | 0.1 | 0.5 | 0.4 | 0.1 | 0.3 | 0.2 | 0.5 | 0.3 | | 1.6 | 0.2 | 1.3 | 0.2 | 3.4 |
| | mean roughness | | | | | | | | | | | | | | | |
| | after reaching B stage (μm) | | | | | | | | | | | | | | | |
| | Dicing property (chip | ○ | ○ | ○ | ○ | ○ | ○ | ○ | ○ | ○ | | × | ○ | × | ○ | × |
| | chipping, chip flying) | | | | | | | | | | | | | | | |
| | Dicing property | ○ | ○ | ○ | ○ | ○ | ○ | ○ | ○ | × | | ○ | ○ | × | ○ | ○ |
| | (resin chipping) | | | | | | | | | | | | | | | |
| | Adhesion to Ni/Au/ | ○ | ○ | ○ | ○ | ○ | ○ | ○ | ○ | ○ | | ○ | × | ○ | × | ○ |
| | Pd-plated lead frame | | | | | | | | | | | | | | | |
| | Adhesion to Ag-plated | ○ | ○ | ○ | ○ | ○ | ○ | ○ | ○ | ○ | | ○ | × | ○ | × | ○ |
| | lead frame | | | | | | | | | | | | | | | |
| | Adhesion to Cu lead frame | ○ | ○ | ○ | ○ | ○ | ○ | ○ | ○ | × | | ○ | × | ○ | × | ○ |
| | Die attach property | ○ | ○ | ○ | ○ | ○ | ○ | ○ | ○ | ○ | | — | ○ | × | ○ | ○ |
| | Moisture and solder | 0/20 | 0/20 | 0/20 | 0/20 | 0/20 | 0/20 | 0/20 | 0/20 | 0/20 | | — | 15/20 | 10/20 | 0/20 | 10/20 |
| | resistance test | | | | | | | | | | | | | | | |
| | Temperature cycle test | 0/20 | 0/20 | 0/20 | 0/20 | 0/20 | 0/20 | 0/20 | 0/20 | 0/20 | | — | 0/20 | 20/20 | 20/20 | 5/10 |

TABLE 2

| | | Working exmple | | | | | Comparative example | | | | | | | |
|---|---|---|---|---|---|---|---|---|---|---|---|---|---|---|
| Composition (part by mass) | | 9 | 10 | 11 | 12 | 13 | 8 | 9 | 10 | 11 | 12 | 13 | 14 | 15 |
| | | Ratios of components in working example 1 except for component E | | | | | | | | | | | | |
| E1 | Spherical filler (μm) | 0.5 | 0.5 | 4.0 | 4.0 | 4.0 | 0.02 | 0.02 | 0.5 | 4.0 | 10 | 10 | 4.0 | 4.0 |
| E2 | Scalelike filler (μm) | 8.0 | 14 | 4.0 | 8.0 | 14 | 4.0 | 17 | 17 | 17 | 4.0 | 17 | 8.0 | 14 |
| Evaluation | Viscosity (P · as) 0.2 rpm | 24 | 20 | 25 | 13 | 5.5 | 187 | 126 | 12 | 7.1 | 5.4 | 3.3 | 14 | 5.7 |
| result | Viscosity (Pa · s) 2 rpm | 20 | 17 | 19 | 12 | 5.0 | 88 | 72 | 10 | 6.0 | 5.0 | 3.0 | 12 | 5.0 |
| | Thixotropic index | 1.2 | 1.2 | 1.3 | 1.1 | 1.1 | 2.1 | 1.8 | 1.2 | 1.2 | 1.1 | 1.1 | 1.2 | 1.1 |
| | Lowest melt viscosity in B | 550 | 320 | 500 | 450 | 470 | 1900 | 1600 | 370 | 280 | 450 | 300 | 420 | 390 |
| | stage (Pa · s) | | | | | | | | | | | | | |
| | Number of meshes per inch | 200 | 200 | 400 | 325 | 200 | 200 | 200 | 200 | 200 | 200 | 200 | 400 | 325 |
| | of mask used | | | | | | | | | | | | | |
| | Void observed immediately | ○ | ○ | ○ | ○ | ○ | ○ | ○ | ○ | ○ | ○ | ○ | ○ | ○ |
| | after printing | | | | | | | | | | | | | |
| | Void observed 30 min after printing | ○ | ○ | ○ | ○ | ○ | ○ | ○ | ○ | ○ | ○ | ○ | ○ | ○ |
| | Surface arithmetic mean roughness | 0.3 | 0.5 | 0.2 | 0.2 | 0.2 | 1.9 | 2.3 | 2.3 | 3.0 | 1.8 | 4.3 | 3.5 | 2.8 |
| | after reaching B stage (μm) | | | | | | | | | | | | | |
| | Dicing property (chip chipping, | ○ | ○ | ○ | ○ | ○ | × | × | × | × | × | × | × | × |
| | chip flying) | | | | | | | | | | | | | |
| | Dicing property (resin chipping) | ○ | ○ | ○ | ○ | ○ | ○ | ○ | ○ | ○ | ○ | ○ | ○ | ○ |
| | Adhesion to Ni/Au/Pd-plated | ○ | ○ | ○ | ○ | ○ | ○ | ○ | ○ | ○ | ○ | ○ | ○ | ○ |
| | lead frame | | | | | | | | | | | | | |
| | Adhesion to Ag-plated lead frame | ○ | ○ | ○ | ○ | ○ | ○ | ○ | ○ | ○ | ○ | ○ | ○ | ○ |
| | Adhesion to Cu lead frame | ○ | ○ | ○ | ○ | ○ | ○ | ○ | ○ | ○ | ○ | ○ | ○ | ○ |
| | Die attach property | ○ | ○ | ○ | ○ | ○ | ○ | × | × | × | ○ | × | × | × |
| | Moisture and solder resistance test | 0/20 | 0/20 | 0/20 | 0/20 | 0/20 | 0/20 | 20/20 | 20/20 | 20/20 | 20/20 | 20/20 | 20/20 | 20/20 |
| | Temperature cycle test | 0/20 | 0/20 | 0/20 | 0/20 | 0/20 | 0/20 | 20/20 | 20/20 | 20/20 | 12/20 | 20/20 | 20/20 | 20/20 |

### INDUSTRIAL APPLICABILITY

The liquid resin composition of the invention can be used to perform screen printing on a wafer. The composition of the invention exhibits a superior adhesiveness to a dicing tape, because it can be quickly defoamed, quickly level screen mesh marks and reach B stage, after printing. Further, the composition of the invention exhibits superior dicing properties at the time of dividing a silicon wafer; and a superior adhesion to a lead frame or the like. For these reasons, the liquid resin composition of the invention is useful as an epoxy resin adhesive employed to manufacture a semiconductor device that is often downsized, highly dense and structurally complex.

1. A liquid resin composition comprising:
(A) an epoxy resin having not less than two epoxy groups in one molecule;
(B) a curing agent having not less than two groups in one molecule that are reactive with epoxy groups, said curing agent being in an amount at which the groups in the component (B) that are reactive with epoxy groups are in an amount of 0.8 to 1.25 equivalents with respect to 1 equivalent of epoxy groups in the component (A);
(C) an acrylic resin having a molecular weight of not lower than 100,000, but lower than 1,000,000, said acrylic resin being in an amount of 5 to 900 parts by mass with respect to a total of 100 parts by mass of the components (A) and (B);
(D) a curing agent in an amount of 0.05 to 10 parts by mass with respect to the total of 100 parts by mass of the components (A) and (B);
(E) an inorganic filler in an amount of 50 to 600 parts by mass with respect to the total of 100 parts by mass of the components (A) and (B);
(F) a diluent in an amount of 10 to 900 parts by mass with respect to a total of 100 parts by mass of the components (A) to (D); and
(G) a dimethyl silicone that is in an amount of 0.01 to 2 parts by mass with respect to the total of 100 parts by mass of the components (A) and (B), and is represented by the following general formula (1) wherein n represents an integer of 0 to 2,000 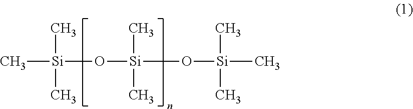
wherein 10 to 90% by mass of said inorganic filler (E) is a spherical or pseudospherical inorganic filler having an average particle diameter of 0.05 to 5 μm, and 90 to 10% by mass of said inorganic filler (E) is a scale-shaped inorganic filler having an average thickness t of 0.005 to 5 μm, an average particle diameter a of 0.05 to 15 μm and an aspect ratio (average particle diameter a/average thickness t) of 2 to 100.

2. The liquid resin composition according to claim 1, wherein a part of the component (A) is a silicone-modified epoxy resin, and/or a part of the component (B) is a silicone-modified curing agent, said silicone-modified components being in an amount of 0.1 to 5 parts by mass with respect to the total of 100 parts by mass of the components (A) and (B).

3. The liquid resin composition according to claim 1, wherein said spherical or pseudospherical inorganic filler is silica, alumina or a combination thereof.

4. The liquid resin composition according to claim 2, wherein said spherical or pseudospherical inorganic filler is silica, alumina or a combination thereof.

5. The liquid resin composition according to claim 1, wherein said scale-shaped inorganic filler is mica, talc or a combination thereof.

6. The liquid resin composition according to claim 2, wherein said scale-shaped inorganic filler is mica, talc or a combination thereof.

7. The liquid resin composition according to claim 1, wherein said diluent (F) is a solvent having a boiling point of 150 to 300° C.

8. The liquid resin composition according to claim 1, wherein said liquid resin composition exhibits a thixotropic index of 0.8 to 1.5.

9. The liquid resin composition according to claim 1, wherein said liquid resin composition in B stage exhibits a lowest melt viscosity of 200 to 100,000 Pas at 50 to 200° C.

10. A silicon chip die attaching method comprising:
(1) applying the liquid resin composition of claim 1 to one surface of a silicon wafer through screen printing;
(2) heating the liquid resin composition applied in (1) at 60 to 200° C. for 1 min to 3 hours to bring the liquid resin composition to a B stage, and forming an adhesion layer having a thickness of not larger than 200 μm and a surface arithmetic mean roughness of not larger than 2 μm;
(3) bonding a silicon wafer to a dicing tape through said adhesion layer;
(4) cutting an adhesion layer-containing silicon wafer prepared in (3) into multiple individual pieces;
(5) peeling an adhesion layer-containing semiconductor chip obtained in (4) from the dicing tape, and mounting said semiconductor chip on a lead frame through the adhesion layer of said semiconductor chip; and
(6) curing the liquid resin composition on the lead frame.

11. The silicon chip die attaching method according to claim 10, wherein an average particle diameter of said scale-shaped inorganic filler as the component (E) of the liquid resin composition is 0.05 to 15 μm when a mask for screen printing in (1) has not less than 40, but less than 300 meshes per inch.

12. The silicon chip die attaching method according to claim 10, wherein an average particle diameter of said scale-shaped inorganic filler as the component (E) of the liquid resin composition is 0.05 to 10 μm when a mask for screen printing in (1) has not less than 300, but less than 400 meshes per inch.

13. The silicon chip die attaching method according to claim 10, wherein an average particle diameter of said scale-shaped inorganic filler as the component (E) of the liquid resin composition is 0.05 to 5 μm when a mask for screen printing in (1) has 400 to 500 meshes per inch.

14. A semiconductor device having a cured product of the liquid resin composition as set forth in claim 1.
